(19) United States
(12) Patent Application Publication
(10) Pub. No.: US 2026/0150344 A1
(43) Pub. Date: May 28, 2026

(54) THIN FILM TRANSISTOR AND STRETCHABLE PANEL AND ELECTRONIC DEVICE

(71) Applicant: Samsung Electronics Co., Ltd., Suwon-si (KR)

(72) Inventors: Kyunghun KIM, Suwon-si (KR); Gae Hwang LEE, Suwon-si (KR)

(73) Assignee: Samsung Electronics Co., Ltd., Suwon-si (KR)

(21) Appl. No.: 19/385,691

(22) Filed: Nov. 11, 2025

(30) Foreign Application Priority Data
Nov. 26, 2024 (KR) 10-2024-0171409

(51) Int. Cl. H10D 30/67; H10D 86/40; H10D 86/60

(52) U.S. Cl. CPC H10D 30/6737; H10D 30/675; H10D 86/423; H10D 86/60

(57) ABSTRACT

Provided are a thin film transistor, a stretchable panel including the same, and an electronic device including the same. The thin film transistor may include a gate electrode, a semiconductor layer overlapping with the gate electrode and including a two-dimensional semiconductor material, and a source electrode and a drain electrode electrically connected to the semiconductor layer and including a two-dimensional conductive material, wherein a constituent element forming the two-dimensional conductive material may be same as a constituent element forming the two-dimensional semiconductor material.

### CROSS-REFERENCE TO RELATED APPLICATION

This application claims priority to and the benefit of Korean Patent Application No. 10-2024-0171409 filed with the Korean Intellectual Property Office on Nov. 26, 2024, the entire contents of which are incorporated herein by reference.

### BACKGROUND

### 1. Field

The present disclosure relates to a thin film transistor, a stretchable panel, and an electronic device.

### 2. Description of the Related Art

In recent years, research is in progress on a stretchable panel such as a display panel that can be curved, bent, or folded or a wearable sensor array that are attached to a living body or an object. Such a stretchable panel may need to have stretchability aspects of being stretched or restored according to motions of the living body or shapes of the object as well as the flexibility of be curved, bent, or folded in a desired and/or alternatively predetermined direction.

### SUMMARY

A stretchable panel, such as a stretchable display panel or a wearable sensor array, may include a plurality of pixels (subpixels) and a plurality of thin film transistors for independently switching or driving each pixel (subpixel). In order to more effectively implement a stretchable panel, each component that constitutes the thin film transistors may have flexibility and stretchability.

Some example embodiments provide a thin film transistor that may reduce or prevent electrical performance degradation while ensuring flexibility and stretchability.

Some example embodiments provide a stretchable panel including the thin film transistor.

Some example embodiments provide an electronic device including the thin film transistor or the stretchable panel.

According to an example embodiment, a thin film transistor may include a gate electrode, a semiconductor layer overlapping the gate electrode and including a two-dimensional semiconductor material, and a source electrode and a drain electrode electrically connected to the semiconductor layer and including a two-dimensional conductive material, wherein a constituent element forming the two-dimensional conductive material may be same as a constituent element forming the two-dimensional semiconductor material.

In some embodiments, the two-dimensional semiconductor material and the two-dimensional conductive material each may be metal chalcogenide or black phosphorus.

In some embodiments, the two-dimensional semiconductor material and the two-dimensional conductive material each may be the metal chalcogenide. The metal chalcogenide may include a metal element and a chalcogen element, and an atomic ratio of the chalcogen element to the metal element of the two-dimensional conductive material may be different from an atomic ratio of the chalcogen element to the metal element of the two-dimensional semiconductor material.

In some embodiments, the atomic ratio of the chalcogen element to the metal element of the two-dimensional conductive material may be lower than the atomic ratio of the chalcogen element to the metal element of the two-dimensional semiconductor material.

In some embodiments, the atomic ratio of the chalcogen element to the metal element of the two-dimensional conductive material may be about 1.0 to about 1.6 and the atomic ratio of the chalcogen element to the metal element of the two-dimensional semiconductor material may be about 1.8 to about 2.0.

In some embodiments, the two-dimensional conductive material may be a metal chalcogenide represented by Chemical Formula 1 and the two-dimensional semiconductor material may be a metal chalcogenide represented by Chemical Formula 2.

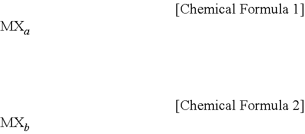

In Chemical Formulas 1 and 2,
M may be at least one metal element,
X may be at least one chalcogen element,
1.0≤a≤1.6, and 1.8≤b≤2.0.

In some embodiments, the metal element may include Mo, W, Nb, Ta, Pt, Pd, Co, Cr, Cu, Ni, In, Bi, Hf, Zr, or Re, and the chalcogen element may include S, Se, or Te.

In some embodiments, the two-dimensional semiconductor material and the two-dimensional conductive material each may have atomic vacancies where some of the constituent elements are missing. The atomic vacancies in the two-dimensional semiconductor material of the semiconductor layer may be less than the atomic vacancies in the two-dimensional conductive material of the source electrode and the drain electrode.

In some embodiments, a crystalline phase of the two-dimensional conductive material may be same as a crystalline phase of the two-dimensional semiconductor material.

In some embodiments, the two-dimensional semiconductor material and the two-dimensional conductive material may each be included in a form of nanoflakes.

In some embodiments, the two-dimensional semiconductor material and the two-dimensional conductive material each may be metal chalcogenide nanoflakes or each may be black phosphorus nanoflakes. The semiconductor layer, the source electrode, and the drain electrode each may include one or more (e.g., two or more) single layers including the metal chalcogenide nanoflakes or the black phosphorus nanoflakes.

In some embodiments, the source electrode, the semiconductor layer, and the drain electrode may be arranged in parallel in an in-plane direction, and an interface between the semiconductor layer and the source electrode and an interface between the semiconductor layer and the drain electrode may be continuous.

According to an embodiment, a thin film transistor may include a source electrode, a semiconductor layer, and a drain electrode. The source electrode, the semiconductor layer, and the drain electrode may be arranged in parallel in an in-plane direction. The source electrode, the semiconductor layer, and the drain electrode may include two-dimensional material nanoflakes with same crystalline phases and same constituent elements.

In some embodiments, the two-dimensional material nanoflakes may be metal chalcogenide nanoflakes or black phosphorus nanoflakes. The source electrode, the semiconductor layer, and the drain electrode each may include one or more (e.g., two or more) single layers including the metal chalcogenide nanoflakes or the black phosphorus nanoflakes.

In some embodiments, the two-dimensional material nanoflakes may be the metal chalcogenide nanoflakes and each may include a metal element and a chalcogen element. An atomic ratio of the chalcogen element to the metal element of the metal chalcogenide nanoflakes in the source electrode and the drain electrode may be lower than an atomic ratio of the chalcogen element to the metal element of the metal chalcogenide nanoflakes in the semiconductor layer.

In some embodiments, the metal chalcogenide nanoflakes in the source electrode and the drain electrode may be represented by Chemical Formula 1, and the metal chalcogenide nanoflakes in the semiconductor layer may be represented by Chemical Formula 2.

In some embodiments, the metal element may include Mo, W, Nb, Ta, Pt, Pd, Co, Cr, Cu, Ni, In, Bi, Hf, Zr, or Re, and the chalcogen element may include S, Se, or Te.

In some embodiments, the two-dimensional material nanoflakes may have atomic vacancies where some of the constituent elements are missing, and the atomic vacancies in the two-dimensional material nanoflakes of the semiconductor layer may be less than the atomic vacancies in the two-dimensional material nanoflakes of the source electrode and the drain electrode.

According to an example embodiment, a stretchable panel may include a stretchable substrate, a thin film transistor array on the stretchable substrate and including the thin film transistor among thin film transistors, and a unit element array including unit elements electrically connected to each of the thin film transistors. The unit elements each may include a light emitting diode, a photoelectric conversion diode, or any combination thereof.

According to some example embodiments, an electronic device including the stretchable panel may be provided.

According to some example embodiments, electrical performance degradation may be reduced or prevented while ensuring flexibility and stretchability of thin film transistors.

According to an example embodiment, a method of manufacturing a thin film transistor (e.g., the thin film transistors as described above) may include: forming a gate electrode; forming a gate insulating layer on the gate electrode; forming a single two-dimensional material pattern on the gate insulating layer with the same two-dimensional material, the single two-dimensional material pattern having conductive properties or semiconductor properties; and modifying the electrical properties of a portion of the single two-dimensional material pattern through post-processing (also referred to as processing) so as to divide the single two-dimensional material pattern into a source electrode, a semiconductor layer, and a drain electrode, wherein the semiconductor layer is electrically connected to the source electrode and the drain electrode, the semiconductor layer includes a two-dimensional semiconductor material, and the source electrode and the drain electrode include a two-dimensional conductive material. The semiconductor layer may overlap the gate electrode. The source electrode, the semiconductor layer, and the drain electrode may be arranged in parallel in an in-plane direction. An interface between the semiconductor layer and the source electrode and an interface between the semiconductor layer and the drain electrode may be continuous.

According to some example embodiments, the single two-dimensional material pattern may have conductive properties, and the method may include selectively post-processing a region to be formed as the semiconductor layer of the single two-dimensional semiconductor material pattern so as to form the two-dimensional semiconductor material, and an unprocessed region of the single two-dimensional semiconductor material pattern may remain as the two-dimensional conductive material.

According to some example embodiments, the single two-dimensional material pattern may have semiconductor properties, and the method may include selectively post-processing regions to be formed as the source electrode and the drain electrode of the single two-dimensional semiconductor material pattern so as to form the two-dimensional conductive material, and an unprocessed region of the single two-dimensional semiconductor material pattern may remain as the two-dimensional semiconductor material.

According to some example embodiments, the post-processing may include heat treatment, surface treatment, doping, or any combination thereof.

According to some example embodiments, the post-processing may include acid treatment. The acid treatment may include supplying an acid to the region to be formed as the semiconductor layer of the single two-dimensional semiconductor material pattern. The acid may include hydrochloric acid, hydrobromic acid, iodic acid, bis(trifluoromethane)sulfonimide (TFSI), or any combination thereof.

According to some example embodiments, the single two-dimensional material pattern may include nanoflakes. The nanoflakes may be obtained by exfoliating bulk crystals with a layered structure. The nanoflakes may be metal chalcogenide nanoflakes or black phosphorus nanoflakes. The single two-dimensional material pattern may include one (e.g., two or more) single layers including the metal chalcogenide nanoflakes or the black phosphorus nanoflakes.

According to some example embodiments, by using the above method, a thin film transistor having the above advantages may be obtained, and also, the process may be simplified, and damage to the semiconductor layer that may occur when forming the source electrode and the drain electrodes after forming the semiconductor layer may be limited and/or prevented.

### BRIEF DESCRIPTION OF THE DRAWINGS

FIG. 1 is a perspective view showing an example of a thin film transistor according to some example embodiments,

FIG. 2 is a cross-sectional view of the thin film transistor of FIG. 1,

FIG. 3 is a plan view schematically showing an example of a source electrode, a semiconductor layer, and a drain electrode in the ‘A’ region of the thin film transistor of FIG. 1,

FIG. 4 is a cross-sectional view schematically showing an example of a nanoflakes arrangement of a source electrode, a semiconductor layer, and a drain electrode in the ‘A’ region of the thin film transistor of FIG. 1,

FIG. 5 is a plan view schematically showing an example of a nanoflakes arrangement of a source electrode, a semiconductor layer, and a drain electrode in the ‘A’ region of the thin film transistor of FIG. 1,

FIG. 6 is a plan view showing an example of a panel for an electronic device according to some example embodiments,

FIG. 7 is a cross-sectional view showing an example of a unit element in the panel for the electronic device of FIG. 6,

FIG. 8 is a plan view showing another example of a panel for an electronic device according to some example embodiments,

FIG. 9 is a graph showing the current characteristics depending on the voltage applied to a sample device according to Preparation Example 2, and

FIG. 10 is a graph showing the current characteristics of a thin film transistor according to Example.

### DETAILED DESCRIPTION

Hereinafter, some example embodiments will be described in detail so that those of ordinary skill in the art may easily implement them. However, applied structures of example embodiments may be implemented in several different forms and are not limited to the embodiments described herein.

In the drawings, the thickness of layers, films, panels, regions, etc., may be exaggerated for clarity. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Additionally, spatially relative terms, such as upper, lower, side, etc. are represented based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Hereinafter, “combination” includes a mixture, a composite, and/or a stacked structure of two or more layers.

An example of a thin film transistor according to some example embodiments is described with reference to the drawings below.

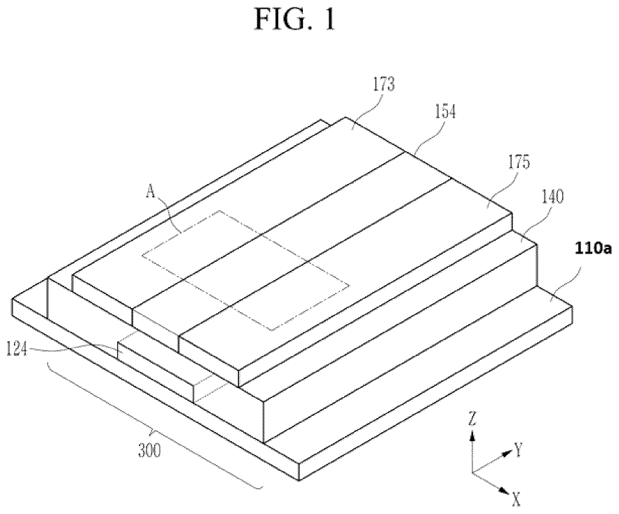

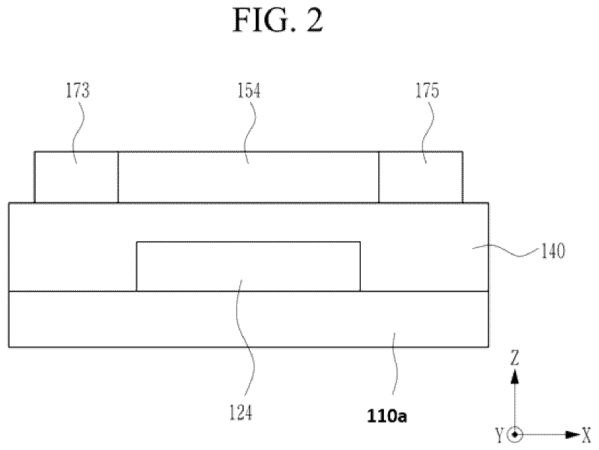

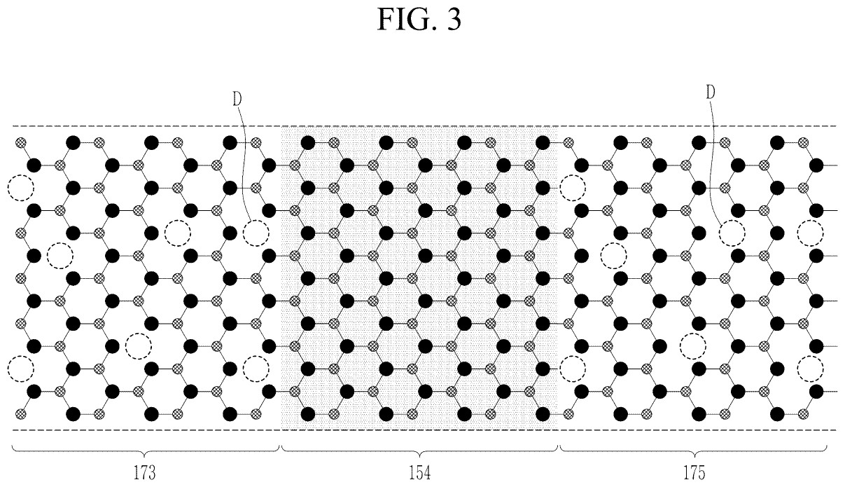

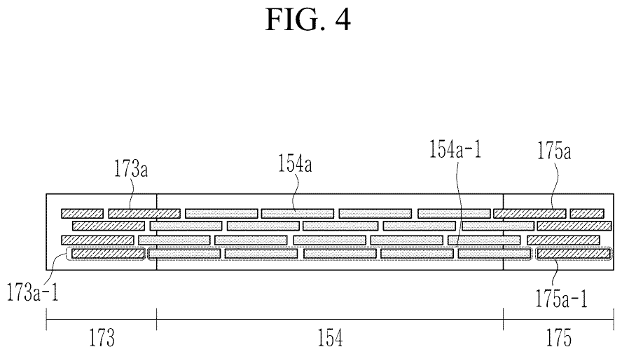

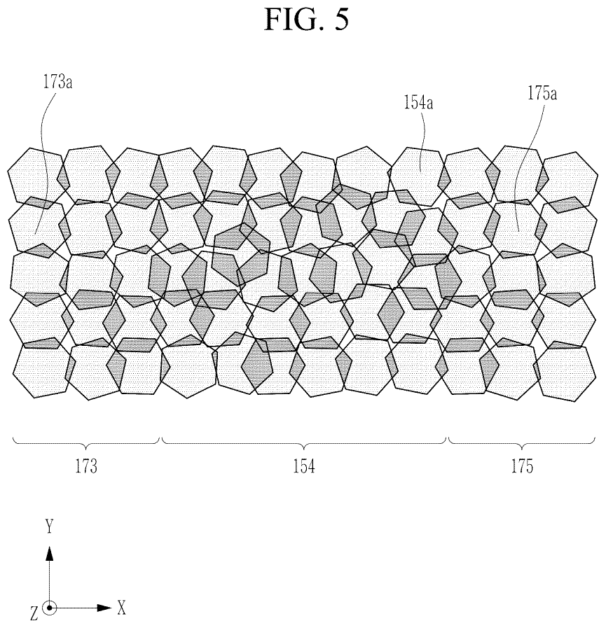

FIG. 1 is a perspective view showing an example of a thin film transistor according to some example embodiments, FIG. 2 is a cross-sectional view of the thin film transistor of FIG. 1, FIG. 3 is a plan view schematically showing an example of a source electrode, a semiconductor layer, and a drain electrode in the ‘A’ region of the thin film transistor of FIG. 1, FIG. 4 is a cross-sectional view schematically showing an example of a nanoflakes arrangement of a source electrode, a semiconductor layer, and a drain electrode in the ‘A’ region of the thin film transistor of FIG. 1, and FIG. 5 is a plan view schematically showing an example of a nanoflakes arrangement of a source electrode, a semiconductor layer, and a drain electrode in the ‘A’ region of the thin film transistor of FIG. 1.

Referring to FIGS. 1 and 2, a thin film transistor 300 according to some example embodiments includes a gate electrode 124, a gate insulation layer 140, a semiconductor layer 154, a source electrode 173, and a drain electrode 175. The thin film transistor 300 may be supported by a substrate 110a, and the substrate 110a may be, for example, a stretchable substrate.

The gate electrode 124 is electrically connected to a gate line (not shown) that transmits a gate signal and is overlapped with a semiconductor layer 154 with a gate insulation layer 140 therebetween. The gate electrode 124 may include, for example, a conductor, such as, but not limited to, a metal such as gold (Au), copper (Cu), nickel (Ni), aluminum (Al), molybdenum (Mo), chromium (Cr), tantalum (Ta), titanium (Ti), or an alloy thereof; a conductive nanostructure such as a conductive nanowire or a conductive nanotube; a liquid metal; a conductive polymer; or any combination thereof. The metal may have a plurality of microcracks, for example microcracked Au configured to be stretchable. The gate electrode 124 may be, for example, a stretchable electrode.

The gate insulation layer 140 may be between the gate electrode 124 and the semiconductor layer 154. In other words, the gate insulation layer 140 may electrically insulate the semiconductor layer 154 from the gate electrode 124. The gate insulation layer 140 may be made of an inorganic insulator, an organic insulator, and/or an organic-inorganic insulator. The inorganic insulator may include, for example, an oxide, a nitride, and/or an oxynitride, including for example, Ag, Mg, Cu, Zr, Zn, Hf, Cr, Al, Co, Fe, Ti, Sn, Si, Ge, Mn, W, Mo, or any combination thereof, for example, Ag₂O, MgO, CuO, ZrO₂, ZnO, HfO₂, Cr₂O₃, Al₂O₃, Co₃O₄, Fe₂O₃, TiO₂, SiO₂, SnO₂, GeO₂, MnO₂, WO₃, MoO₃, or any combination thereof, but is not limited thereto. The organic insulator and/or the organic-inorganic insulator may be for example, a stretchable insulator, for example, polyorganosiloxane, a polymer including a butadiene structural unit, a polymer including an olefin structural unit, a polymer including a urethane structural unit, a polymer including an acrylic structural unit, or any combination thereof, and may include, for example, polydimethylsiloxane (PDMS), styrene-ethylene-butylene-styrene copolymer (SEBS), styrene-ethylene-propylene-styrene copolymer (SEPS), styrene-butadiene-styrene copolymer (SBS), styrene-isobutylene-styrene copolymer (SIBS), or any combination thereof, but is not limited thereto. The gate insulation layer 140 may have, for example, one layer or two or more layers.

The semiconductor layer 154, the source electrode 173, and the drain electrode 175 are formed on the gate insulation layer 140. The semiconductor layer 154 may be overlapped with the gate electrode 124 along the thickness direction (e.g., z direction). The source electrode 173 is electrically connected to a data line (not shown) that transmits a data signal and faces the drain electrode 175 with a semiconductor layer 154 therebetween. The source electrode 173 and the drain electrode 175 may be electrically connected to the semiconductor layer 154.

The source electrode 173, the semiconductor layer 154, and the drain electrode 175 may be disposed in parallel along one direction (e.g., the X direction) in the same plane (e.g., the XY direction), and for example, one side of the semiconductor layer 154 may be in contact with the source electrode 173 and the other side of the semiconductor layer 154 may be in contact with the drain electrode 175.

The semiconductor layer 154 and the source/drain electrodes 173 and 175 may each include a two-dimensional material. The two-dimensional material may be a planar inorganic nanomaterial extending along two axes (e.g., X-axis and Y-axis). For example, the length extending along the X-axis and the width extending along the Y-axis may be significantly larger than the thickness extending along the Z-axis, and for example, the length extending along the X-axis and the width extending along the Y-axis may each independently be tens of nanometers to several micrometers, and the thickness extending along the Z-axis may be on the order of angstroms to several nanometers corresponding to the thickness of an atom.

The two-dimensional material may be, for example, a metal chalcogenide or black phosphorus (BP). The metal chalcogenide may include at least one metal and at least one chalcogen element, and may be, for example, represented by MX_{c}. Here, M may be a metal element (e.g., a transition metal) and may include, for example, Mo, W, Nb, Ta, Pt, Pd, Co, Cr, Cu, Ni, In, Bi, Hf, Zr or Re, X may be a chalcogen element and may include, for example, S, Se or Te, and c may be 1 to 2. The metal chalcogenide may have a structure in which one layer of a metal elements M is sandwiched between two layers of chalcogen elements X, and may have a two-dimensional structure with a very thin thickness. The black phosphorus may have a two-dimensional structure, in which phosphorus P elements are arranged in a wrinkled honeycomb shape, with a very thin thickness.

The semiconductor layer 154 and the source/drain electrodes 173 and 175 may include two-dimensional materials with different electrical properties. That is, the semiconductor layer 154 may include a two-dimensional semiconductor material exhibiting semiconductor properties, and the source/drain electrodes 173 and 175 may include a two-dimensional conductive material exhibiting conductive properties.

The semiconductor layer 154 and the source/drain electrodes 173 and 175 may be formed from a single two-dimensional material pattern including the same two-dimensional material. The two-dimensional material pattern may have conductive properties or semiconductor properties. For example, by coating or depositing a two-dimensional material to form a two-dimensional material pattern and modifying the electrical properties of a portion of the two-dimensional material pattern through post-processing, regions with different electrical properties, e.g., a two-dimensional semiconductor material and a two-dimensional conductive material, may be formed.

For example, in a two-dimensional material pattern with conductive properties, a region to be formed as a semiconductor layer 154 may be selectively post-processed to form a two-dimensional semiconductor material, and an unprocessed region may remain as a two-dimensional conductive material. For example, in a two-dimensional material pattern with semiconductor properties, a region to be formed as source/drain electrodes 173 and 175 may be selectively post-processed to form a two-dimensional conductive material, and an unprocessed region may remain as a two-dimensional semiconductor material. The post-processing may include controlling of atomic vacancies in the two-dimensional material pattern, for example, heat treatment, surface treatment, doping, or any combination thereof, but is not limited thereto.

In this way, the two-dimensional semiconductor material and the two-dimensional conductive material are formed from a single two-dimensional material pattern, and thus may have the same constituent elements and the same crystalline phase. For example, the two-dimensional semiconductor material and the two-dimensional conductive material may include metal chalcogenides having the same metal element and chalcogen element and the same crystalline phase (e.g., 2H phase). For example, the two-dimensional semiconductor material and the two-dimensional conductive material may each be black phosphorus composed of phosphorus elements and having an orthorhombic crystalline phase.

In addition, since the source electrode 173, the semiconductor layer 154, and the drain electrode 175 are formed from a single two-dimensional material pattern, they may have a substantially continuous crystal structure, and accordingly, the interface between the semiconductor layer 154 and the source electrode 173 and the interface between the semiconductor layer 154 and the drain electrode 175 may be seamless and continuous. Therefore, the contact resistance between the semiconductor layer 154 and the source electrode 173 and between the semiconductor layer 154 and the drain electrode 175 may be effectively reduced.

In addition, since the source electrode 173, the semiconductor layer 154, and the drain electrode 175 are formed from a single two-dimensional material pattern, the process may be simplified compared to forming the semiconductor layer 154 and the source/drain electrodes 173 and 175 in separate processes, and damage to the semiconductor layer 154 that may occur when forming the source/drain electrodes 173 and 175 after forming the semiconductor layer 154 may be limited and/or prevented.

The two-dimensional material pattern may include two-dimensional material in the form of nanoflakes (hereinafter referred to as “nanoflakes”). The nanoflakes may be very thin exfoliated pieces obtained by exfoliating bulk crystals with a layered structure, for example, by mechanical exfoliation and/or solution-phase exfoliation (chemical exfoliation). The two-dimensional material may be, for example, metal chalcogenide nanoflakes or black phosphorus nanoflakes.

The nanoflakes may have a number of lattice defects that are generated during the exfoliation process, and these lattice defects may be mainly generated during the dispersion process, such as by strong ultrasonic during the intercalation and/or exfoliation steps. The lattice defects may be, for example, multiple atomic vacancies caused by the missing of constituent elements that make up the exfoliated nanoflakes. For example, when the two-dimensional material is metal chalcogenide nanoflakes, a large number of chalcogen vacancies may be generated by the missing of chalcogen atoms during the exfoliation step.

The multiple atomic vacancies (e.g., chalcogen vacancies) may provide electron transport paths in the exfoliated nanoflakes, thereby determining the electrical properties of the exfoliated nanoflakes. For example, if there are a large number of atomic vacancies in the exfoliated nanoflakes, the two-dimensional material may have conductive properties, and if there are no or small numbers of atomic vacancies in the exfoliated nanoflakes, the two-dimensional material may have semiconductor properties.

The aforementioned two-dimensional material pattern may be formed by coating or depositing exfoliated nanoflakes and thus may have inherently conductive properties. In addition, the semiconductor properties may be obtained through post-processing for reducing or removing atomic vacancies existing in some regions of the two-dimensional material pattern, e.g., regions where semiconductor layers 154 are to be formed. The post-processing for reducing or removing atomic vacancies may be performed by a variety of methods, including, for example, a passivation of the atomic vacancies by an acid treatment in which acid is supplied to the two-dimensional material pattern to perform a hydrogenation reaction. Here, the acid may be a strong acid, and the strong acid may be, for example, hydrochloric acid, hydrobromic acid, iodic acid, bis(trifluoromethane)sulfonimide (TFSI), or any combination thereof. The atomic vacancies in a two-dimensional material pattern may be reduced or eliminated by passivation through the acid treatment.

Referring to FIG. 3, by such post-processing, the two-dimensional material pattern may be divided into regions with different electrical properties, e.g., a semiconductor layer 154 with semiconductor properties and source/drain electrodes 173 and 175 with conductive properties. The semiconductor layer 154 may have substantially no atomic vacancies or significantly fewer atomic vacancies (e.g., chalcogen vacancies) through post-processing, and the source/drain electrodes 173 and 175 may have multiple atomic vacancies D without post-processing.

Referring to FIGS. 4 and 5 together with FIGS. 2 and 3, the semiconductor layer 154 may include nanoflakes (hereinafter referred to as “first nanoflakes”) 154a including the two-dimensional material (two-dimensional semiconductor material) with semiconductor properties, and the source/drain electrodes 173 and 175 may include nanoflakes (hereinafter referred to as “second nanoflakes”) 173a and 175a including the two-dimensional material (two-dimensional conductive material) with conductive properties by having multiple atomic vacancies without post-processing. The first nanoflakes 154a and the second nanoflakes 173a and 175a may each be metal chalcogenide nanoflakes or black phosphorus nanoflakes.

The first nanoflakes 154a may be arranged along the in-plane direction (XY direction) of the semiconductor layer 154, and adjacent first nanoflakes 154a may be separated or partially stacked from each other. The first nanoflakes 154a arranged in the in-plane direction (XY direction) may form a first nanoflake single layer 154a-1, and adjacent first nanoflake single layers 154a-1 may be spaced apart from each other by a distance of angstroms to several nanometers.

The second nanoflakes 173a and 175a may be arranged along the in-plane direction (XY direction) of the source electrode 173 and the drain electrode 175, and adjacent second nanoflakes 173a and 175a may be separated or partially stacked from each other. The second nanoflakes 173a and 175a arranged in the in-plane direction (XY direction) may form second nanoflake single layers 173a-1 and 175a-1, and adjacent second nanoflake single layers 173a-1 and 175a-1 may be spaced apart from each other by a distance of angstroms to several nanometers.

Van der Waals interactions may occur between first nanoflakes 154a arranged in the in-plane direction, between second nanoflakes 173a and 175a arranged in the in-plane direction, between adjacent first nanoflake single layers 154a-1, and/or between adjacent second nanoflake single layers 173a-1 and 175a-1, respectively. When the substrate 110a is stretched, the first nanoflake 154a, the second nanoflakes 173a and 175a, the second nanoflake single layers 173a-1 and 175a-1, and/or the second nanoflake single layers 173a-1 and 175a-1, which are weakly bonded by Van der Waals interaction, may slide and/or rotate, and thus maintain electrical properties without breaking, and accordingly, the semiconductor layer 154 and the source/drain electrodes 173 and 175 may be the stretchable semiconductor layer 154 and the stretchable source/drain electrodes 173 and 175, respectively.

For example, the two-dimensional semiconductor material in the semiconductor layer 154 and the two-dimensional conductive material in the source/drain electrodes 173 and 175 may be a metal chalcogenide including at least one metal element and at least one chalcogen element. In other words, the two-dimensional semiconductor material may be a metal chalcogenide (metal chalcogenide nanoflake) with semiconductor properties, and the two-dimensional conductive material may be a metal chalcogenide (metal chalcogenide nanoflake) with conductive properties. As described above, the metal chalcogenide with semiconductor properties and the metal chalcogenide with conductive properties may have the same constituent elements and the same crystalline phases but different electrical properties due to differences in the number of atomic vacancies D (e.g., chalcogen vacancies).

The metal chalcogenide (metal chalcogenide nanoflake), as described above, may include at least one metal element and at least one chalcogen element, and for example, be represented by MX_{c} (M is a metal, e.g., a transition metal, X is a chalcogen element, and c is about 1 to about 2). However, the metal chalcogenide (metal chalcogenide nanoflake), which is the two-dimensional semiconductor material in the semiconductor layer 154, and the metal chalcogenide (metal chalcogenide nanoflake), which is the two-dimensional conductive material in the source/drain electrodes 173/175, may have a different atomic ratio of chalcogen elements to metal element due to a difference in the atomic vacancies (e.g., chalcogen vacancies). For example, the atomic ratio of chalcogen elements to metal elements of the two-dimensional conductive material in the source/drain electrodes 173/175 may be lower than the atomic ratio of chalcogen elements to metal elements of the two-dimensional semiconductor material in the semiconductor layer 154. For example, the atomic ratio of chalcogen elements to metal elements of the two-dimensional conductive material in the source/drain electrodes 173/175 may be about 1.0 to about 1.6, and the atomic ratio of chalcogen elements to metal elements of the two-dimensional semiconductor material in the semiconductor layer 154 may be about 1.8 to about 2.0.

For example, the two-dimensional conductive material in the source/drain electrodes 173 and 175 may be a metal chalcogenide represented by Chemical Formula 1, and the two-dimensional semiconductor material in the semiconductor layer 154 may be a metal chalcogenide represented by Chemical Formula 2.

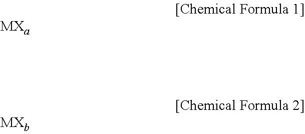

In Chemical Formulas 1 and 2,
M may be at least one metal element, and for example, may include Mo, W, Nb, Ta, Pt, Pd, Co, Cr, Cu, Ni, In, Bi, Hf, Zr, or Re,
X may be at least one chalcogen element, and for example, may include S, Se or Te,
1.0≤a≤1.6 and 1.8≤b≤2.0. For example, a may satisfy 1.1≤a≤1.5, or 1.2≤a≤1.4. It should be understood that a and b in Chemical Formulas 1 and 2 may each indicate the total amount of the at least one chalcogen element, in other words, a ratio of the total number of atoms of the at least one chalcogen element to the total number of atoms of the at least one metal element.

For example, the two-dimensional conductive material in the source/drain electrodes 173 and 175 may include MoSₐ, Mo(Se)ₐ, Mo(SSe)ₐ, Mo(STe)ₐ, Mo₍₁₋ₚ₎WₚSₐ, Mo₍₁₋ₚ₎WₚSeₐ, Mo₍₁₋ₚ₎WₚTeₐ, Mo₍₁₋ₚ₎NbₚSₐ, Mo₍₁₋ₚ₎NbₚSeₐ, Mo₍₁₋ₚ₎TaₚSₐ, Mo₍₁₋ₚ₎TaₚSeₐ, Mo₍₁₋ₚ₎Wₚ(SSe)ₐ, MoTeₐ, WSₐ, WSeₐ, W(SSe)ₐ, WTeₐ, W(STe)a, W₍₁₋ₚ₎NbₚSₐ, W₍₁₋ₚ₎NbₚSeₐ, PtSₐ, PtSeₐ, PtTeₐ, PdSeₐ, HfSₐ, HfSeₐ, HfTeₐ, ZrSₐ, ZrSeₐ, ZrTeₐ, ReSₐ, ReSeₐ, ReTeₐ, TaSₐ, TaSeₐ, Ta₍₁₋ₚ₎WₚSₐ, Ta₍₁₋ₚ₎WₚSeₐ (wherein 0≤p≤1 and 1.0≤a≤1.6), or any combination thereof, but is not limited thereto. When more than one kind of chalcogen elements are included, “a” in the above chemical formulae represents the total amount of the more than one kind of chalcogen elements. Take “Mo(SSe)ₐ” for example, “a” represents the total amount of S and Se, wherein a ratio of S to Se is not particularly limited, as long as none of the amounts of S and Se is 0.

The two-dimensional semiconductor material in the semiconductor layer 154 may include MoS_{b}, Mo(Se)_{b}, Mo(SSe)_{b}, Mo(STe)_{b}, Mo₍₁₋ₚ₎WₚS_{b}, Mo₍₁₋ₚ₎WₚSe_{b}, Mo₍₁₋ₚ₎WₚTe_{b}, Mo₍₁₋ₚ₎NbₚS_{b}, Mo₍₁₋ₚ₎NbₚSe_{b}, Mo₍₁₋ₚ₎TaₚS_{b}, Mo₍₁₋ₚ₎TaₚSe_{b}, Mo₍₁₋ₚ₎Wₚ(SSe)_{b}, MoTe_{b}, WS_{b}, WSe_{b}, W(SSe)_{b}, WTe_{b}, W(STe)_{b}, W₍₁₋ₚ₎NbₚS_{b}, W₍₁₋ₚ₎NbₚSe_{b}, PtS_{b}, PtSe_{b}, PtTe_{b}, PdSe_{b}, HfS_{b}, HfSe_{b}, HfTe_{b}, ZrS_{b}, ZrSe_{b}, ZrTe_{b}, ReS_{b}, ReSe_{b}, ReTe_{b}, TaS_{b}, TaSe_{b}, Ta₍₁₋ₚ₎WₚS_{b}, Ta₍₁₋ₚ₎WₚSe_{b} (wherein 0≤p≤1 and 1.8≤b≤2.0), or any combination thereof, but is not limited thereto. When more than one kind of chalcogen elements are included, “b” in the above chemical formulae represents the total amount of the more than one kind of chalcogen elements. Take “Mo(SSe)_{b}” for example, “b” represents the total amount of S and Se, wherein a ratio of S to Se is not particularly limited, as long as none of the amounts of S and Se is 0.

In FIG. 1, a bottom gate structure thin film transistor is illustrated as an example of a thin film transistor 300, but the present disclosure is not limited thereto and may be applied to a top gate structure in which a gate electrode 124 is on top of a semiconductor layer 154.

The aforementioned thin film transistor 300 may be repeatedly arranged, for example, along rows and/or columns, on the substrate 110a to form a thin film transistor array. The thin film transistor array may be included in a panel for an electronic device.

For example, the panel for an electronic device may be a stretchable panel.

For example, the panel for an electronic device may be a display panel, a sensor array panel or a sensor embedded display panel.

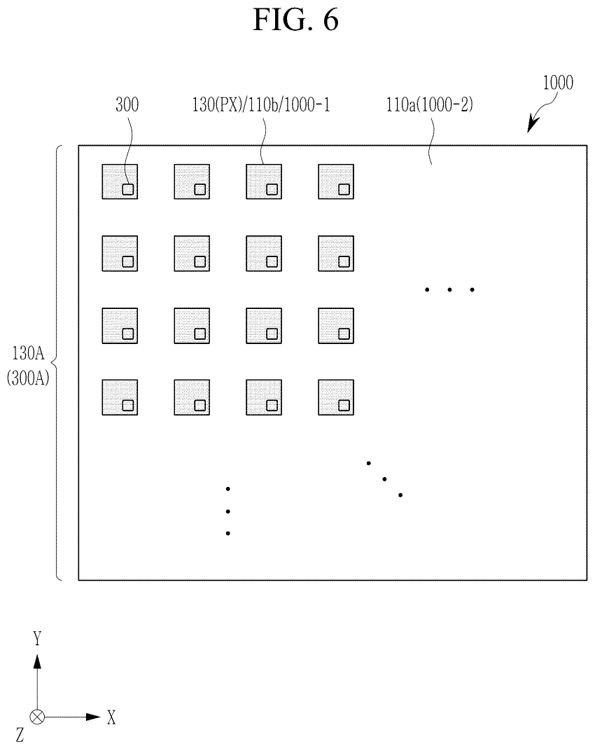

FIG. 6 is a plan view showing an example of a panel for an electronic device according to some example embodiments.

Referring to FIG. 6, the panel 1000 for an electronic device according to some example embodiments includes a substrate 110a, a thin film transistor array 300A arranged on the substrate 110a, and a unit element array 130A.

The substrate 110a, may be, for example, a glass substrate, a polymer substrate, or a semiconductor substrate, wherein the polymer substrate may be, for example, a stretchable substrate.

The panel 1000 for an electronic device may include regions having a different elastic modulus along an in-plane direction (e.g., XY direction) of the substrate 110a, for example, a high elastic modulus region 1000-1 with a relatively higher elastic modulus and a low elastic modulus region 1000-2 with a relatively lower elastic modulus.

The high elastic modulus region 1000-1 may be a region in which resistance to external force such as twisting, pressing, and pulling is relatively high, so that it may be not substantially deformed by the external force or a deformation degree is very small. That is, the high elastic modulus region 1000-1 may include a stretch resistance region with very low stretchability due to a large resistance to stretching, in addition to a region with no stretchability at all.

The high elastic modulus region 1000-1 may be a region in which a non-stretchable pattern 110b with a high elastic modulus is covered on a substrate 110a, and accordingly, the high elastic modulus region 1000-1 may have substantially the same planar shape as the non-stretchable pattern 110b. The notion that elements are “substantially the same” may indicate that the elements may be completely the same and may also indicate that the elements may be determined to be the same in consideration of errors or deviations occurring during a process.

The elastic modulus of the high elastic modulus region 1000-1 may be determined by the elastic modulus of the non-stretchable pattern 110b. For example, the elastic modulus of the non-stretchable pattern 110b may be about 100 times or more higher than that of the substrate 110a, within the above range, about 300 times or more, about 500 times or more, or about 1000 times or more, and within the above range, about 100 times to about 10⁸ times, about 500 times to about 10⁸ times, about 1000 times to about 10⁸ times, about 10 times to about 10⁷ times, about 50 times to about 10⁷ times, about 100 times to about 10⁷ times, about 500 times to about 10⁷ times, or about 10³ times to about 10⁷ times. For example, the elastic modulus of the non-stretchable pattern 110b may be about 10⁴ Pa to about 10¹² Pa, but is not limited thereto. Due to the high elastic modulus of the non-stretchable pattern 110b, the high elastic modulus region 1000-1 may not be substantially stretched or deformed even if the substrate 110a is stretched in a desired and/or alternatively predetermined direction.

The non-stretchable pattern 110b may include an organic material, an inorganic material, an organic-inorganic material, or any combination thereof, with a relatively high elastic modulus, for example polycarbonate, polymethylmethacrylate, polyethyleneterephthalate, polyethylenenaphthalate, polyimide, polyamide, polyamideimide, polyethersulfone, or any combination thereof, but is not limited thereto.

The non-stretchable pattern 110b may be formed by, for example, coating or depositing a material (e.g., an organic material) with a relatively high elastic modulus on the substrate 110a and partially removing it by, for example, etching, to leave the non-stretchable pattern 110b only in the portion corresponding to the high elastic modulus region 1000-1. However, the present disclosure is not limited thereto, and the high elastic modulus region 1000-1 and the low elastic modulus region 1000-2 with different elastic moduli may be implemented by forming the non-stretchable pattern 110b on the substrate 110a in various ways.

The high elastic modulus region 1000-1 may be arranged, for example, along rows and/or columns, and the unit elements 130 may be arranged in the high elastic modulus region 1000-1. A unit element 130 arranged in a high elastic modulus region 1000-1 may define a pixel or a subpixel PX.

The low elastic modulus region 1000-2 is a region that may flexibly respond to external forces such as twisting, pressing, and pulling, and may be a region excluding the high elastic modulus region 1000-1. The low elastic modulus region 1000-2 may be a region where the non-stretchable pattern 110b is not covered on the substrate 110a and may be relatively uniformly arranged on the entire surface of the panel 1000 for the electronic device.

The elastic modulus of the low elastic modulus region 1000-2 may be substantially equal to the elastic modulus of the substrate 110a. The substrate 110a may include an elastomer with a relatively low elastic modulus, for example, an elastomer (including organic and inorganic elastomer), an inorganic elastomer-like material, or any combination thereof.

The elastomer may include for example polyorganosiloxane, a polymer including a butadiene structural unit, a polymer including an olefin structural unit, a polymer including a urethane structural unit, a polymer including an acrylic structural unit, or any combination thereof, for example polydimethylsiloxane, thermoplastic polyurethane (TPU), a styrene-ethylene-butylene-styrene copolymer (SEBS), styrene-ethylene-propylene-styrene copolymer (SEPS), styrene-butadiene-styrene copolymer (SBS), styrene-isoprene-styrene copolymer (SIS), styrene-isobutyrene-styrene copolymer (SIBS), or any combination thereof, but is not limited thereto. The inorganic elastomer-like material may include, for example, but not limited to, a ceramic with elasticity, a solid metal, a liquid metal, or any combination thereof. An elastic modulus of the elastomer may be, for example, about 100 Pa to about 10⁹ Pa, but is not limited thereto.

The high elastic modulus region 1000-1 may be surrounded and isolated by the low elastic modulus region 1000-2, but is not limited thereto. Conversely, the low elastic modulus region 1000-1 may be surrounded and isolated by the high elastic modulus region 1000-2.

The thin film transistor array 300A may include a plurality of thin film transistors 300 on the high elastic modulus region 1000-1, for example, arranged along rows and/or columns. Each of the thin film transistors 300 is the same as described above.

The unit element array 130A includes, for example, a plurality of unit elements 130 arranged along rows and/or columns, and each of the unit elements may be, for example, a light emitting diode such as an organic light emitting diode, an inorganic light emitting diode, a quantum dot light emitting diode, a micro light emitting diode, or a perovskite light emitting diode or a photoelectric conversion diode such as an organic photoelectric conversion diode, an inorganic photoelectric conversion diode, or an organic-inorganic photoelectric conversion diode, which may be the same or different one another. Each of the unit elements 130 may define a pixel or a subpixel PX.

As an example, each unit element 130 may be a light emitting diode configured to independently emit light of red, green or blue wavelength regions, or any combination thereof to display red, green, blue, or any combination thereof.

As an example, each unit element 130 may be a photoelectric conversion diode configured to selectively absorb light of red, green, blue or infrared wavelength region, or any combination thereof, and convert the absorbed light into an electrical signal.

For example, some of the unit elements 130 may be a light emitting diode and some of the unit elements 130 may be a photoelectric conversion diode.

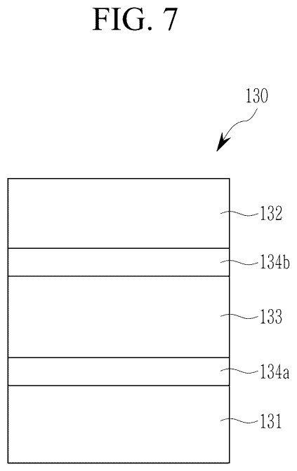

FIG. 7 is a cross-sectional view showing an example of a unit element in the panel for the electronic device of FIG. 6.

Referring to FIG. 7, the unit element 130 may be a light emitting diode or a photoelectric conversion diode and may include an anode 131; a cathode 132; an active layer 133 between the anode 131 and the cathode 132, and optionally auxiliary layers 134a and 134b between the anode 131 and the active layer 133 and/or between the cathode 132 and the active layer 133.

At least one of the anode 131 or the cathode 132 may be a light transmitting electrode. For example, the anode 131 may be a light transmitting electrode and the cathode 132 may be a reflective electrode. For example, the anode 131 may be a reflective electrode and the cathode 132 may be a light transmitting electrode. For example, the anode 131 and the cathode 132 may each be a light transmitting electrode. At least one of the anode 131 or the cathode 132 may be a stretchable electrode, and the stretchable electrode may have, for example, a plurality of microcracks, and since the plurality of microcracks are separated from each other like small holes, flexibility may be provided to the stretchable electrode by extending along the stretching direction during stretching while maintaining the electrical movement path in the stretchable electrode.

The active layer 133 may be a light emitting layer or a photoelectric conversion layer.

The light emitting layer may be configured to emit light in a red wavelength region, a green wavelength region, a blue wavelength region, an infrared wavelength region, or any combination thereof, and may include, for example, an organic light emitting layer, an inorganic light emitting layer (including a quantum dot light emitting layer), an organic-inorganic light emitting layer, or any combination thereof. The light emitting layer may include at least one host material and at least one dopant.

The photoelectric conversion layer may be configured to absorb light in a red wavelength region, a green wavelength region, a blue wavelength region, an infrared wavelength region, or any combination thereof, and convert the absorbed light into an electrical signal, and may be an organic photoelectric conversion layer, an inorganic photoelectric conversion layer, an organic-inorganic photoelectric conversion layer, or any combination thereof. The photoelectric conversion layer may include a p-type semiconductor and an n-type semiconductor, and the p-type semiconductor and the n-type semiconductor may form a pn junction.

The auxiliary layers 134a and 134b may be, for example, charge auxiliary layers, and may be, for example, a hole transport layer, a hole injection layer, an electron blocking layer, an electron transport layer, an electron injection layer, a hole blocking layer, or any combination thereof, but are not limited thereto.

Each unit element 130 may be independently controlled and/or driven by one or more thin film transistors, at least some of which may be the aforementioned thin film transistors 300. For example, at least one thin film transistor 300 may be included in each pixel (subpixel), and each unit element 130 and the thin film transistor 300 may be electrically connected to each other. The description of the thin film transistor 300 is as described above.

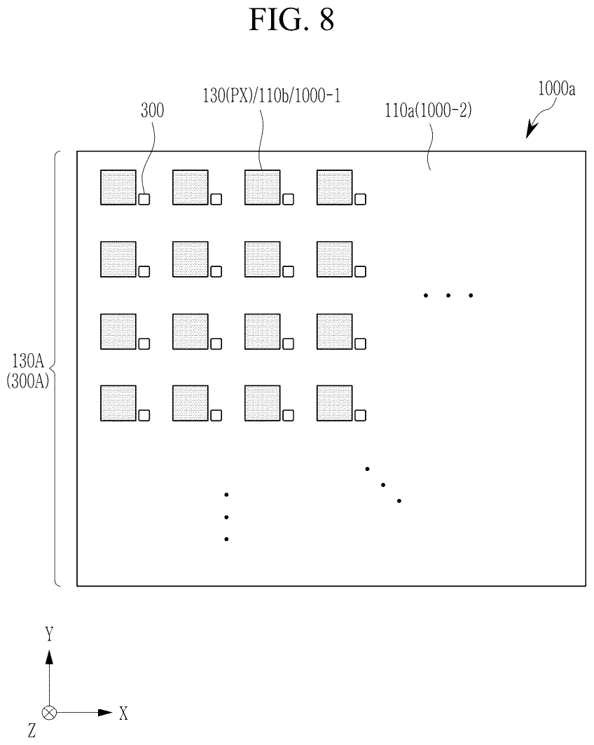

FIG. 8 is a plan view showing another example of a panel for an electronic device according to some example embodiments.

Referring to FIG. 8, the panel 1000a for an electronic device according to the present example may include, similar to the example panel 1000 described above, a substrate 110a, a thin film transistor array 300A arranged on the substrate 110a, and a unit element array 130A.

However, unlike the above-described example, the panel 1000a for an electronic device according to the present example may have at least a portion of the thin film transistor array 300A in the low elastic modulus region 1000-2. As described above, the thin film transistor 300 may include a two-dimensional material in the semiconductor layer 154, the source electrode 173, and the drain electrode 175, so that the thin film transistor 300 may have stretchability and thus may be flexibly stretched against external force and restored even though the thin film transistor 300 are disposed in the low elastic modulus region 1000-2.

In this way, by disposing at least some of the thin film transistors 300 forming the thin film transistor array 300A in a region other than the pixel PX (low elastic modulus region 1000-2), an area occupied by the thin film transistors in the pixel or subpixel PX may be reduced compared to a structure in which all thin film transistors are disposed in each pixel or subpixel PX.

Therefore, the space limitation of the pixels or subpixels PX due to the low elastic modulus region 1000-2 for stretching may be overcome, the pixel size may be reduced, and the number of pixels or subpixels PX per unit area may be increased accordingly. For example, the number of pixels or subpixels PX per unit area in the panel 1000 for an electronic device may be greater than or equal to about 150 ppi (pixel per inch), greater than or equal to about 200 ppi, greater than or equal to about 250 ppi, greater than or equal to about 300 ppi, greater than or equal to about 350 ppi, greater than or equal to about 400 ppi, greater than or equal to about 450 ppi, or greater than or equal to about 500 ppi and may be, for example, about 150 ppi to about 1000 ppi, about 200 ppi to about 1000 ppi, about 250 ppi to about 1000 ppi, about 300 ppi to about 1000 ppi, about 350 ppi to about 1000 ppi, about 400 ppi to about 1000 ppi, about 450 ppi to about 1000 ppi, or about 500 ppi to about 1000 ppi.

Any one of the aforementioned panels 1000 and 1000a for an electronic device may be applied to various fields, and may be, for example, a display panel, a sensor array, or a sensor-embedded display panel. Any one of the panels 1000 and 1000a for an electronic device may be, for example, a panel for a stretchable electronic device, for example, a bendable display panel, a foldable display panel, a rollable display panel, a wearable device, a skin-like display panel, a skin-like sensor array, a large-area conformable display, smart clothing, and the like, but is not limited thereto.

For example, the stretchable sensor array may be attached to a living body in the form of a very thin patch or band to monitor biometric information in real time, for example, a sensor array including a photoplethysmographic (PPG) sensor, wherein the biometric information may include heart rate, oxygen saturation, stress, arrhythmia, blood pressure, etc. and be obtained by analyzing a wave form of electrical signals.

The thin film transistor 300 or any one of the panels 1000 and 1000a for an electronic device may be included in various electronic devices, and the electronic devices may further include a processor (not shown) and a memory (not shown).

The electronic devices may include, for example, mobile phones, video phones, smart phones, smart pads, smart watches, digital cameras, tablet PCs, laptop PCs, notebook computers, computer monitors, wearable computers, televisions, digital broadcasting terminals, e-books, personal digital assistants (PDAs), PMP (portable multimedia player), EDA (enterprise digital assistant), head mounted displays (HMD), in-vehicle navigations, Internet of Things (IoT), Internet of Everything (IoE), security devices, and medical devices, but are not limited thereto.

Hereinafter, the embodiments are illustrated in more detail with reference to examples. However, these examples are exemplary, and the present scope is not limited thereto.

### Preparation Example 1: Preparation of Two-Dimensional Semiconductor Material

MoS₂ crystals (2D Semiconductor Inc.) are immersed in a tetraheptylammonium bromide (98%, Sigma Aldrich Co. Ltd.) dispersion (a dispersion medium: 40 mL of anhydrous acetonitrile (99.8%, Sigma-Aldrich Co. Ltd.), a concentration: 5 mg/mL), and then, a constant current of 0.01 A is applied thereto for 60 minutes to intercalate tetraheptylammonium cations into the MoS₂ crystals. After intercalating the tetraheptylammonium cations, the MoS₂ crystals are rinsed with ethanol (99.9%, Sigma-Aldrich Co., Ltd.) and then, ultrasonicated in anhydrous dimethyl formamide (99.9%, Sigma-Aldrich Co., Ltd.) including polyvinylpyrrolidone (PVP, an average molecular weight: 40,000 g/mol, Sigma-Aldrich Co., Ltd.) (40 mL, 8 mg/mL) for 5 minutes. Subsequently, the ultrasonicated dispersion is once centrifuged at a relative centrifugal force of 440 g for 15 minutes to take a supernatant, which is three times centrifuged at a relative centrifugal force of 22000 g for 15 minutes to obtain precipitated MoS₂ nanoflakes (crystalline phase: 2H phase). Subsequently, after changing the solvent to isopropylalcohol (IPA), an excessive amount of PVP or contaminants are removed to prepare an MoS₂ nanoflakes dispersion.

### Preparation Example 2: Manufacturing of Sample Device

A sample device is manufactured in the following method to evaluate electrical properties of a MoS₂ pattern formed using the MoS₂ nanoflakes dispersion according to Preparation Example 1.

Au is thermally deposited on a SEBS substrate (H1052, Asahi KASEI) to form two Au electrodes spaced 100 μm apart. Subsequently, the MoS₂ nanoflakes dispersion according to Preparation Example 1 is coated on the Au electrodes by a spin-casting and then, dried at 200° C. for 10 minutes in a nitrogen glove box to remove the remaining solvent and moisture to form a 10 nm-thick MoS₂ pattern to contact to the two Au electrodes, manufacturing the sample device.

### Evaluation I

The electrical conductivity of the MoS₂ pattern is evaluated by applying a voltage to the two Au electrodes of the sample device according to Preparation Example 2 and measuring a current flowing through the MoS₂ pattern using Keithley 4200-SCS.

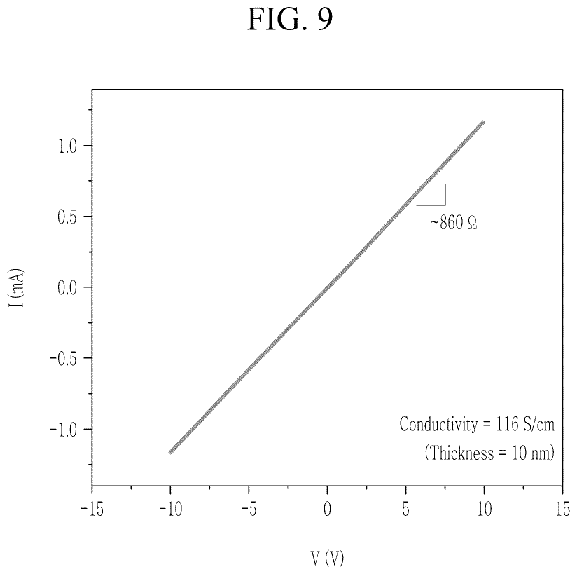

The result is shown in FIG. 9.

FIG. 9 is a graph showing the current characteristics depending on the voltage applied to a sample device according to Preparation Example 2.

Referring to FIG. 9, it may be confirmed that the sample device according to Preparation Example 2 has current characteristics increased proportionally depending on the voltage applied thereto and high electrical conductivity of 116 S/cm. From this, it may be confirmed that the sample device according to Preparation Example 2 has conductive characteristics.

### Example: Manufacturing of Thin Film Transistor

On the p-type doped silicon wafer (gate electrode) on which a 100 nm-thick SiO₂ is formed, silicon oxide is deposited to form a 300 nm-thick gate insulation layer. Subsequently, the MoS₂ nanoflakes dispersion according to Preparation Example 1 is spin-coated on the gate insulation layer to form an MoS₂ pattern with a thickness of 10 nm to 20 nm. Then, a photoresist is applied on the MoS₂ pattern and then, exposed and developed to form a photoresist pattern that exposes only a portion of the MoS₂ pattern (a region where a semiconductor layer is supposed to be formed). Subsequently, the resultant is dipped in bis(trifluoromethane)sulfonyl imide (TFSI) solution (solvent: 1,2-dichloroethane, 10 mg/mL) for 60 minutes and then, dried to acid-treat the exposed portion of the MoS₂ pattern (the region where a semiconductor layer is supposed to be formed). Subsequently, the resultant is dried at 200° C. for 10 minutes in a nitrogen glove box to remove the remaining solvent and moisture. Subsequently, the photoresist pattern is removed to distinguish the MoS₂ pattern into the semiconductor layer including the acid-treated MoS₂ nanoflakes and source/drain electrode including the non-acid-treated MoS₂ nanoflakes, manufacturing a thin film transistor.

### Evaluation II

The thin film transistor according to Example is analyzed with respect to constituent elements forming the semiconductor layer and the source/drain electrode.

The constituent element analysis is performed by using X-ray photoelectron spectroscopy (XPS).

As a result of the constituent element analysis, an S to Mo atomic ratio in the semiconductor layer is higher than about 1.8, but an S to Mo atomic ratio of the source/drain electrode is less than about 1.6.

Accordingly, it may be confirmed that the S to Mo atomic ratio in the MoS₂ pattern may be adjusted by the acid treatment.

### Evaluation III

The thin film transistor according to Example is evaluated with respect to electrical properties.

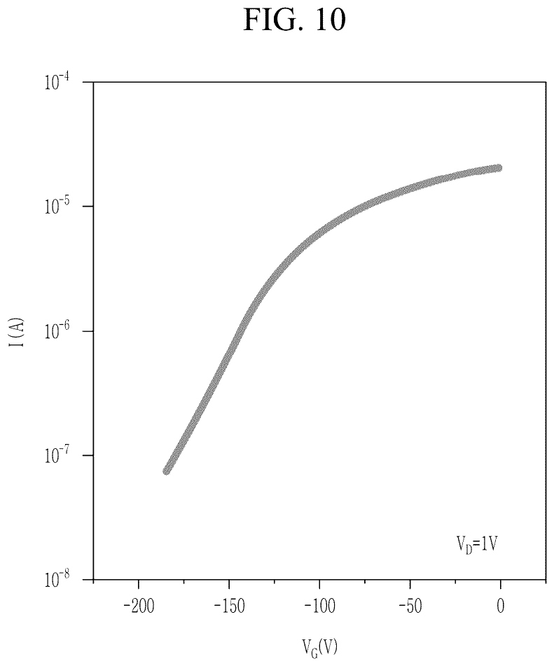

FIG. 10 is a graph showing the current characteristics of the thin film transistor according to Example.

Referring to FIG. 10, the thin film transistor according to Example exhibits satisfactory current characteristics depending on a voltage.

Accordingly, it may be confirmed that the semiconductor layer including the acid-treated MoS₂ nanoflakes of the thin film transistor according to Example has satisfactory semiconductor properties.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical example embodiments, it is to be understood that the inventive concepts are not limited to the disclosed embodiments. On the contrary, it is intended to cover various modifications and equivalent arrangements included within the spirit and scope of the appended claims.

What is claimed is:

1. A thin film transistor, comprising
a gate electrode,
a semiconductor layer overlapping the gate electrode, the semiconductor layer comprising a two-dimensional semiconductor material, and
a source electrode and a drain electrode electrically connected to the semiconductor layer, the source electrode and the drain electrode comprising a two-dimensional conductive material,
wherein a constituent element forming the two-dimensional conductive material is same as a constituent element forming the two-dimensional semiconductor material.

2. The thin film transistor of claim 1, wherein the two-dimensional semiconductor material and the two-dimensional conductive material are each metal chalcogenide or each black phosphorus.

3. The thin film transistor of claim 2, wherein
the two-dimensional semiconductor material and the two-dimensional conductive material are each the metal chalcogenide,
the metal chalcogenide includes a metal element and a chalcogen element, and
an atomic ratio of the chalcogen element to the metal element of the two-dimensional conductive material is different from an atomic ratio of the chalcogen element to the metal element of the two-dimensional semiconductor material.

4. The thin film transistor of claim 3, wherein the atomic ratio of the chalcogen element to the metal element of the two-dimensional conductive material is lower than the atomic ratio of the chalcogen element to the metal element of the two-dimensional semiconductor material.

5. The thin film transistor of claim 4, wherein
the atomic ratio of the chalcogen element to the metal element of the two-dimensional conductive material is about 1.0 to about 1.6, and
the atomic ratio of the chalcogen element to the metal element of the two-dimensional semiconductor material is about 1.8 to about 2.0.

6. The thin film transistor of claim 3, wherein
the two-dimensional conductive material is a metal chalcogenide represented by Chemical Formula 1, and
the two-dimensional semiconductor material is a metal chalcogenide represented by Chemical Formula 2, 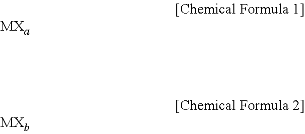
wherein, in Chemical Formulas 1 and 2,
M is at least one metal element,
X is at least one chalcogen element,
1.0≤a≤1.6, and 1.8≤b≤2.0.

7. The thin film transistor of claim 6, wherein
the metal element comprises Mo, W, Nb, Ta, Pt, Pd, Co, Cr, Cu, Ni, In, Bi, Hf, Zr, or Re, and
the chalcogen element comprises S, Se, or Te.

8. The thin film transistor of claim 1, wherein
the two-dimensional semiconductor material and the two-dimensional conductive material each have atomic vacancies where some of the constituent elements are missing, and
the atomic vacancies in the two-dimensional semiconductor material of the semiconductor layer are less than at least one of the atomic vacancies of the two-dimensional conductive material in the source electrode and the atomic vacancies of the two-dimensional conductive material in the drain electrode.

9. The thin film transistor of claim 1, wherein a crystalline phase of the two-dimensional conductive material is same as a crystalline phase of the two-dimensional semiconductor material.

10. The thin film transistor of claim 1, wherein the two-dimensional semiconductor material and the two-dimensional conductive material are each included in a form of nanoflakes.

11. The thin film transistor of claim 10, wherein
the two-dimensional semiconductor material and the two-dimensional conductive material are each metal chalcogenide nanoflakes or are each black phosphorus nanoflakes, and
the semiconductor layer, the source electrode, and the drain electrode each comprise one or more single layers including the metal chalcogenide nanoflakes or the black phosphorus nanoflakes.

12. The thin film transistor of claim 1, wherein
the source electrode, the semiconductor layer, and the drain electrode are disposed in parallel in an in-plane direction, and
an interface between the semiconductor layer and the source electrode is continuous and an interface between the semiconductor layer and the drain electrode is continuous.

13. A thin film transistor, comprising:
a source electrode; a
semiconductor layer; and a
drain electrode, wherein
the source electrode, the semiconductor layer, and the drain electrode are disposed in parallel in an in-plane direction, and
the source electrode, the semiconductor layer, and the drain electrode comprise two-dimensional material nanoflakes with same crystalline phases and same constituent elements.

14. The thin film transistor of claim 13, wherein
the two-dimensional material nanoflakes are metal chalcogenide nanoflakes or black phosphorus nanoflakes, and
the source electrode, the semiconductor layer, and the drain electrode each comprise one or more single layers including the metal chalcogenide nanoflakes or the black phosphorus nanoflakes.

15. The thin film transistor of claim 14, wherein
the two-dimensional material nanoflakes are the metal chalcogenide nanoflakes and each include a metal element and a chalcogen element, and
an atomic ratio of the chalcogen element to the metal element of the metal chalcogenide nanoflakes included in the source electrode and the drain electrode is lower than an atomic ratio of the chalcogen element to the metal element of the metal chalcogenide nanoflakes included in the semiconductor layer.

16. The thin film transistor of claim 15, wherein
the metal chalcogenide nanoflakes in the source electrode and the drain electrode are represented by Chemical Formula 1, and
the metal chalcogenide nanoflakes in the semiconductor layer are represented by Chemical Formula 2: 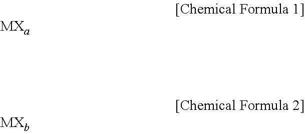
wherein, in Chemical Formulas 1 and 2,
M is at least one metal element,
X is at least one chalcogen element,
1.0≤a≤1.6, and 1.8≤b≤2.0.

17. The thin film transistor of claim 16, wherein
the metal element comprises Mo, W, Nb, Ta, Pt, Pd, Co, Cr, Cu, Ni, In, Bi, Hf, Zr, or Re, and
the chalcogen element comprises S, Se, or Te.

18. The thin film transistor of claim 13, wherein
the two-dimensional material nanoflakes have atomic vacancies where some of the constituent elements are missing, and
the atomic vacancies in the two-dimensional material nanoflakes of the semiconductor layer are less than the atomic vacancies in the two-dimensional material nanoflakes of the source electrode and the drain electrode.

19. A stretchable panel, comprising
a stretchable substrate;
a thin film transistor array on the stretchable substrate, the thin film transistor array comprising thin film transistors, wherein each of the thin film transistors includes the thin film transistor of claim 1, and
a unit element array comprising unit elements electrically connected to each of the thin film transistors
wherein the unit elements each comprises a light emitting diode, a photoelectric conversion diode, or any combination thereof.

20. An electronic device comprising:
the stretchable panel of claim 19.
